(19) United States
(12) Patent Application Publication
(10) Pub. No.: US 2023/0047767 A1
(43) Pub. Date: Feb. 16, 2023

(54) METHOD FOR REMOVING FLUOROPOLYMER LIFT-OFF LAYER

(71) Applicant: SOLVAY SPECIALTY POLYMERS ITALY S.P.A., Bollate (Milano) (IT)

(72) Inventors: Jung-Yul Lee, Anyang- si (KR); Dong-Cheol Choe, Incheon (KR); Min-Soo Yoon, Seoul (KR); Laura Ponta, Milano (IT); Mattia Bassi, Milano (IT)

(73) Assignee: SOLVAY SPECIALTY POLYMERS ITALY S.P.A., Bollate (Milano) (IT)

(21) Appl. No.: 17/784,939

(22) PCT Filed: Dec. 11, 2020
(86) PCT No.: PCT/EP2020/085828

§ 371 Date: Jun. 13, 2022

(30) Foreign Application Priority Data
Dec. 12, 2019 (EP) 19215451.6

(51) Int. Cl. G03F 7/004; C08F 214/18; G03F 7/027

(52) U.S. Cl. CPC G03F 7/0046; C08F 214/18; G03F 7/027

(57) ABSTRACT

The invention pertains to a method of removing a layer of a lift-off fluoropolymer layer from a substrate using a particular stripping solvent, and to a lithographic process using said combination of lift-off fluoropolymer and stripping solvent, in particular for the manufacture of OLED devices.

### CROSS-REFERENCE TO RELATED APPLICATION

This application claims priority to earlier European Patent Application N° 19215451.6, filed on 12 Dec. 2019, the whole content of this application being incorporated herein by reference for all purposes.

### TECHNICAL FIELD

The present invention pertains to a method of removing a layer of a lift-off fluoropolymer from a substrate using a particular stripping solvent, and to a lithographic process using said combination of lift-off fluoropolymer and stripping solvent.

### BACKGROUND ART

Fluoropolymers have been already used in the past in lithographic processes, and more specifically as protective layers in certain photolithographic methods, whereas the creation of a sacrificial fluoropolymer layer is required for protecting/preserving chemical integrity of substrate during either radiation exposure of photoresist(s) and/or etching of photoresist(s) layers.

Document U.S. Pat. No. 9,899,636 discloses a method of making an OLED device which includes:
a) providing a device substrate having a first array of bottom electrodes and a second array of bottom electrodes;
b) providing a first undercut lift-off structure over the device substrate having a first pattern of openings corresponding to the first array of bottom electrodes;
c) depositing one or more first organic EL medium layers including at least a first light-emitting layer over the first undercut lift-off structure and over the first array of bottom electrodes;
d) removing the first undercut lift-off structure and overlying first organic EL medium layer(s) by treatment with a first lift-off agent comprising a fluorinated solvent to form a first intermediate structure;
e) providing a second undercut lift-off structure over the first intermediate structure having a second pattern of openings corresponding to the second array of bottom electrodes;
f) depositing one or more second organic EL medium layers including at least a second light-emitting layer over the second undercut lift-off structure and over the second array of bottom electrodes;
g) removing the second undercut lift-off structure and overlying second organic EL medium layer(s) by treatment with a second lift-off agent comprising a fluorinated solvent to form a second intermediate structure; and
h) providing a common top electrode in electrical contact with the first and second organic EL medium layers.

The undercut lift-off structure includes a fluorinated material base layer and an overlying photoresist layer developed using a fluorinated solvent selected from those that are perfluorinated or highly fluorinated liquids at room temperature, which are immiscible with water and many organic solvents. Among those solvents, hydrofluoroethers (HFEs), including segregated HFEs, are recommended as preferred solvents because they are non-flammable, have zero ozone-depletion potential, lower global warming potential than PFCs and show very low toxicity to humans.

Similarly, document U.S. Pat. No. 9,768,384 discloses a method of manufacturing an organic light-emitting display apparatus including forming a liftoff layer containing a fluoropolymer on a substrate, forming a photoresist on the liftoff layer and patterning the photoresist by removing a portion thereof, etching, using a first solvent, the liftoff layer in a region where the photoresist is removed so that a portion of the liftoff layer remains on the substrate, forming an organic light-emitting layer as etch stop layer above the liftoff layer that remains on the substrate and above a region where the photoresist remains on the liftoff layer, and removing, using a second solvent, the liftoff layer under the region where the photoresist remains on the liftoff layer. Fluoropolymer may contain at least one of polytetrafluoroethylene, polychlorotrifluoroethylene, polydichlorodifluoroethylene, a copolymer of chlorotrifluoroethylene and dichlorodifluoroethylene, a copolymer of tetrafluoroethylene and perfluoroalkylvinylether, a copolymer of chlorotrifluoroethylene and perfluoroalkylvinylether, a copolymer of tetrafluoroethylene and perfluoroalkylvinylether, and a copolymer of chlorotrifluoroethylene and perfluoroalkylvinylether. First and second solvents contain fluorine and generally are hydrofluoroethers, such as those of 3M NOVEC® 7100, 7300 and 7500.

Still in a similar manner, U.S. Pat. No. 9,091,913 discloses a method for producing a spatially patterned structure on a substrate, including the steps of:
(1) forming a layer of a material on at least a portion of a substructure of said spatially patterned structure;
(2) forming a barrier layer of a fluorinated material on said layer of material to provide an intermediate structure;
(3) forming a layer of a photoresist on said barrier layer;
(4) exposing said photoresist to spatially patterned radiation;
(5) developing said photoresist to substantially remove one of exposed or unexposed regions of said photoresist to provide a pattern of uncovered regions of barrier material between regions covered by photoresist;
(6) removing portions of said barrier material that are uncovered by said photoresist to provide a pattern of uncovered regions of said layer of material;
(7) exposing said intermediate structure to at least one of a second material or radiation to cause at least one of a chemical change or a structural change to at least a portion of said intermediate structure; and
(8) removing remaining portions of said barrier layer using a fluorinated solvent. In the said method, the fluorinated material barrier layer substantially protects said layer of said material from chemical and structural changes during said forming said layer of said photoresist and said exposing said photoresist. The fluorinated material may be a fluorinated polymer, such as notably materials known under brand names CYTOP® or TEFLON®-AF which are known for including alicylic structure in main chain, or may be fluorinated compounds of formula CₙF₍₂ₙ₊₂₎; while this document acknowledges that the presence of other chemical moieties beside CF₂ may be tolerated, it specifically teaches that —COOH groups would greatly alter the solubility property and therefore —COOH compounds (carboxylic acids) may not be suitable. The solvents used for the removal of such fluoropolymer barrier layer encompass perfluorodecaline, perfluoro(1,2- or 1,3-dimethylcyclohexane, perfluorokerosene, perfluoro(methyldecalin), perfluoroheptane mixed isomers, and, more generally, volatile fluorinated solvents. The method of this document can be used for creating diode junctions.

In this area, nonetheless, for a method involving removal of lift-off layer made from a fluorinated polymer to be particularly adapted to be used in an OLED lithographic process, the removal shall comply with certain diverging requirements: it shall maintain substantially un-modified, with no swelling by nor adsorption of stripping solvent by the underlying layer(s), including e.g. electron transporting layers or light emitting layers, and shall provide rapid, effective and exhaustive removal of fluorinated polymer from the same layers, so as not to impair, because of fluorinated residues, the electroluminescence performances of the light emitting layers.

While certain materials such as the aforementioned CYTOP® or TEFLON®-AF have been tested in this field of use, and removed with fluorosolvents such as hydrofluoroethers, there remains a need in this area for providing an improved method for removing a lift-off/protective layer made from fluorinated polymer from a subtrate.

### SUMMARY OF INVENTION

A first object of the present invention is hence a method of at least partially removing a lift-off layer [layer (LO)] made of a composition (C_{LO}) comprising at least one fluoropolymer comprising:
repeating units having an alicyclic structure in main chain of said fluoropolymer and derived from at least one fluoromonomer A, and, optionally,
repeating unit derived from at least one fluoromonomer B different from fluoromonomer A,

said fluoropolymer:
possessing an intrinsic viscosity of less than 30 cc/g, when measured at 30° C. in perfluorohexane as solvent; and
comprising an amount of carboxylic end groups of less than 8 mmol/kg;

said method comprising:
providing an assembly comprising a support material having regions covered by a layer (LO);
contacting said assembly with a stripping solvent mixture comprising:
a) at least one fluorinated solvent [solvent (F)] having a Hansen solubility parameter δ_{T} of less than 15.0 MPa^{1/2};
b) from 10 to 10000 ppm, based on weight of solvent (F), of at least one polar organic solvent different from solvent (F) [solvent (P)], said solvent (P) possessing a Hansen solubility parameter δ_{T} of at least 20.0 MPa^{1/2} and of at most 26.0 MPa^{1/2},

so as to obtain at least partial removal of said layer (LO).

The Applicant has surprisingly found that by carefully (i) selecting a polymer (F) possessing said alicyclic structure in the main chain, fulfilling the above recited requirements of intrinsic viscosity, and content of carboxylic end groups, and (ii) selecting a peculiar stripping solvent mixture, including a fluorinated solvent having low Hansen solubility parameter and a minor amount of another solvent having higher Hansen solubility parameter, it is possible to achieve effective removal of lift-off layer, without detrimentally affecting properties of substrate or of other layers of the assembly.

### BRIEF DESCRIPTION OF FIGURE

FIG. 1 is a graph depicting normalized luminescence as a function of time for a reference OLED device, assembled with no use of lift-off layer, for device (1), manufactured applying a lift-off layer and removing the same according to the invention, and for device (2C) of comparison, not manufactured according to the method of the invention.

### DESCRIPTION OF EMBODIMENTS

### The Polymer (F)

As used herein, the expression “fluoromonomer” is to be understood to encompass monomers possessing at least one fluorine atom bound to a carbon atom. The said fluoromonomer may or may not comprise hydrogen atom(s) bound to its carbon atoms. When the fluoropolymer does not comprise any hydrogen atom(s) bound to its carbon atoms, said fluoromonomer will be referred to as a “perfluoromonomer”.

As said, polymer (F) comprises repeating units having an alicyclic structure in main chain of said fluoropolymer and derived from at least one fluoromonomer A. The fluoromonomer A of the polymer (F) of the present invention specifically includes two types of fluoromonomers, i.e. fluoromonomers having an alicyclic structure in their monomeric form and fluoromonomers which do not have an alicylic structure in their monomeric form, but which upon cyclopolymerization provide for an alicyclic structure in the resulting repeating unit of polymer (F).

Fluoromonomer A is preferably a perfluoromonomer.

The repeating unit derived from said fluoromonomer A is preferably represented by any one of the following formulae (1) to (3):

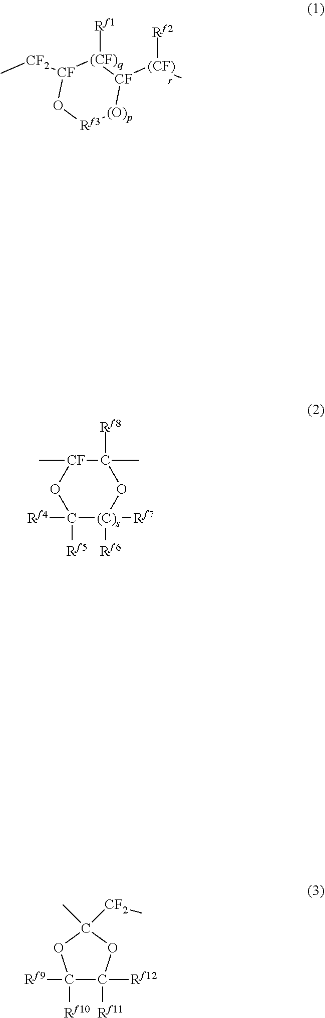

wherein:
in the formula (1) each of p, q and r which are independent of each other, is 0 or 1, each of R^{f1} and R^{f2} which may be the same or different, is a fluorine atom, a C₁-C₅ perfluoroalkyl group or a C₁-C₅ perfluoroalkoxy group, and R^{f3} is a C₁-C₃ perfluoroalkylene group, which may have a C₁-C₅ perfluoroalkyl group or a C₁-C₅ perfluoroalkoxy group, as a substituent;
in the formula (2), s is 0 or 1, each of R^{f4}, R^{f5}, R^{f6} and R^{f7} which may be the same or different, is a fluorine atom or a C₁-C₅ perfluoroalkyl group, and R^{f8} is a fluorine atom, a C₁-C₅ perfluoroalkyl group or a C₁-C₅ perfluoroalkoxy group, provided that R^{f4} and R^{f5} may be connected to form a spiro ring when s=0; and
in the formula (3), each of R^{f9}, R^{f10}, R^{f11} and R^{f12} which may be the same or different, is a fluorine atom or a C₁₋C₅ perfluoroalkyl group or a C₁₋C₅ perfluoroalkoxy group.

The structure of the repeating unit of the above formula (1) may be advantageously derived from fluoromonomers which do not have an alicylic structure in their monomeric form, but which upon cyclopolymerization provide for an alicyclic structure in the repeating unit derived therefrom. As said, in formula (1) above, the perfluoroalkylene group represented by R^{f3} may have a C₁-C₅ perfluoroalkyl group or a C₁-C₅ perfluoroalkoxy group bonded as a substituent. Further, generally, in the formula (1), when q=o, then r=1 and/or alternatively when q=1, then r=0. Specific examples of repeating units of formula (1) include notably those represented by the following formulae (4) to (19):

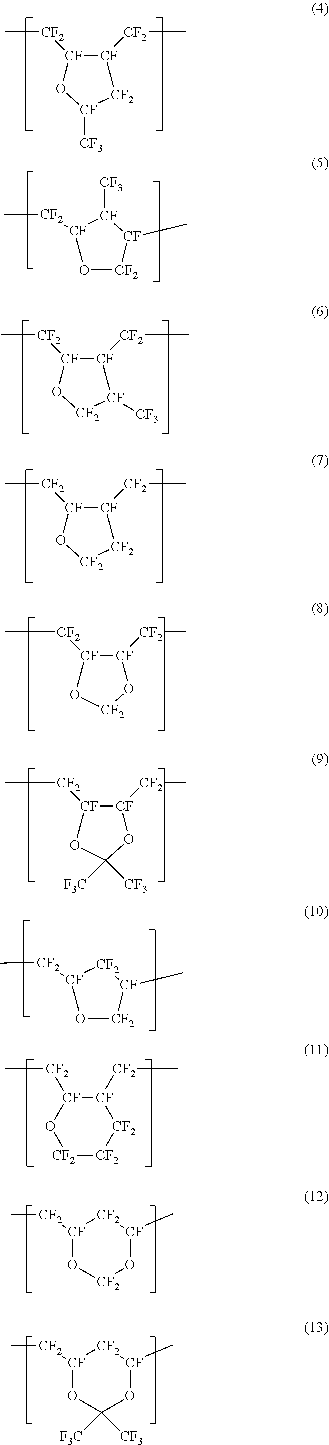

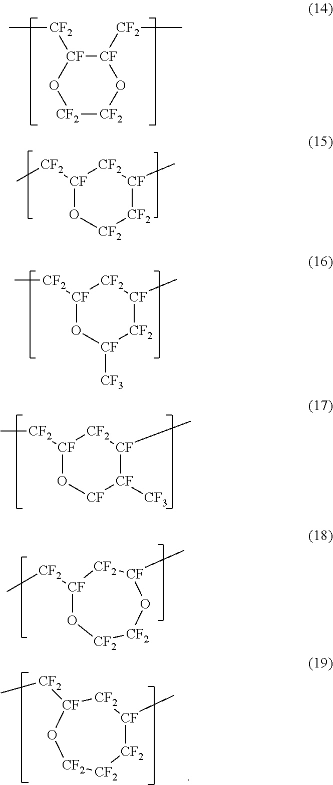

Among repeating units of the above formula (1), preferred are repeating units of formula (4), as above detailed.

Recurring units of formula (4) are obtained advantageously from radical cyclopolymerization of perfluoro(3-butenyl vinyl ether) of formula (4A): CF₂═CF—O—CF₂—CF₂—CF═CF₂.

Further, the structure of the repeating unit of the above formula (2) may be advantageously derived from a fluoromonomer having an alicyclic structure in its monomeric structure. Further, in a case where in the structure of the repeating unit of the formula (2), when the spiro ring formed by R^{f4} and R^{f5} when s=0, is a 4- to 6-membered ring, such a ring may contain an ether oxygen atom as an element constituting the ring, and such a ring may have a perfluoroalkyl group bonded as a substituent.

Specific examples of repeating units of formula (2) include notably those represented by the following formulae (20) to (30):

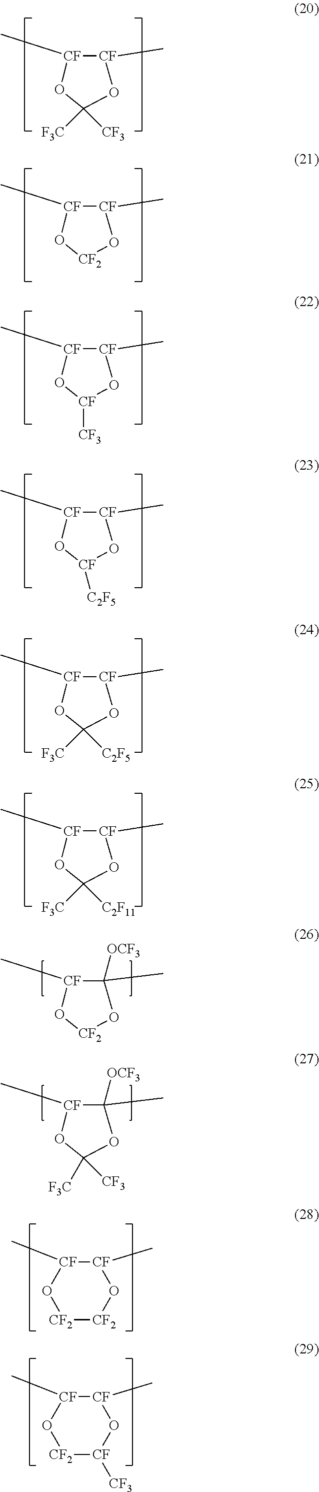

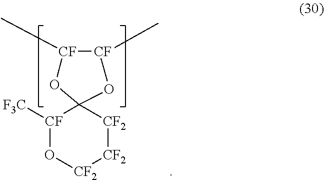

Among repeating units of the above formula (2), preferred are repeating units of formula (20), (21) and (26), as above detailed. Recurring units of formula (20), (21) and (26) are obtained advantageously from radical polymerization of perfluoro(2,2-dimethyl-1,3-dioxole) of formula (20A), perfluoro(1,3-dioxole) of formula (21A), and 2,2,4-trifluoro-5-trifluoromethoxy-1,3-dioxole of formula (26A), respectively:

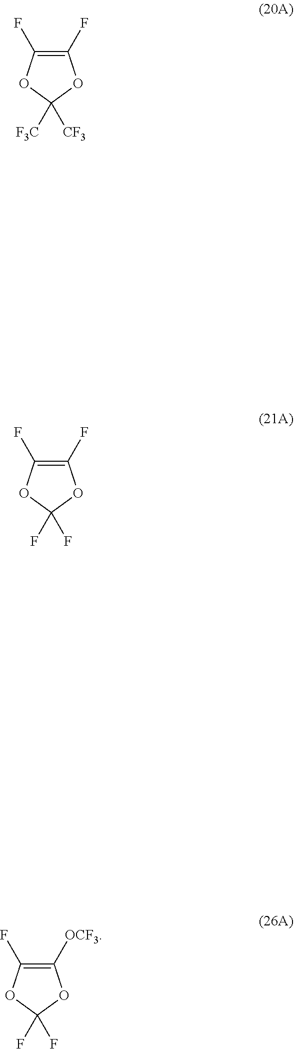

Further, the structure of the repeating unit of the above formula (3) may be advantageously derived from a fluoromonomer having an alicyclic structure in its monomeric structure.

Specific examples of repeating units of formula (3) include notably those represented by the following formulae (31) to (33):

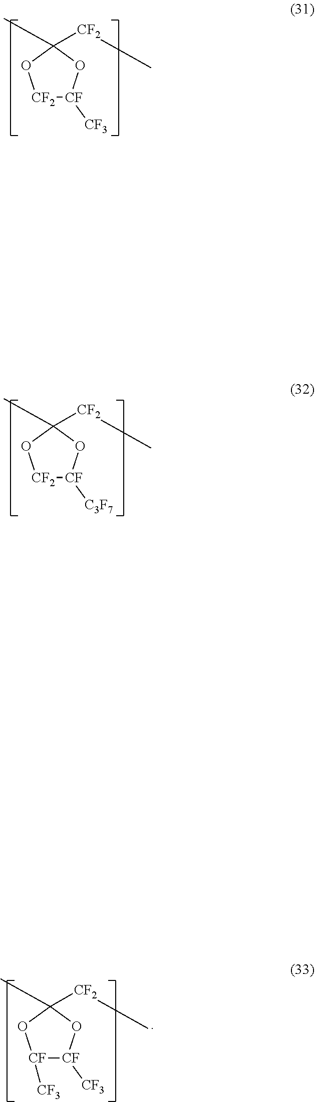

Among repeating units of the above formula (3), preferred are repeating units of formula (31), as above detailed. Repeating units of formula (31) are derived from perfluoro(2-methylene-4-methyl-1,3-dioxolane) of formula (31A):

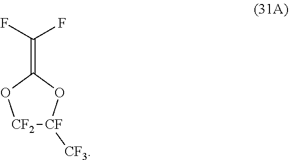

As said, polymer (F) may comprise repeating unit derived from at least one fluoromonomer B different from fluoromonomer A.

Fluoromonomer B may be selected from the group consisting of:
(a) C₂-C₈ perfluoroolefins such as tetrafluoroethylene (TFE), hexafluoropropylene (HFP);
(b) hydrogen-containing C₂-C₈ fluoroolefins, such as vinylidene fluoride (VDF), vinyl fluoride, trifluoroethylene (TrFE), hexafluoroisobutylene (HFIB), perfluoroalkyl ethylenes of formula CH₂═CH—R_{f1}, wherein R_{f1} is a C₁-C₆ perfluoroalkyl group;
(c) C₂-C₈ chloro- and/or bromo-containing fluoroolefins such as chlorotrifluoroethylene (CTFE);
(d) perfluoroalkylvinylethers (PAVE) of formula CF₂═CFOR_{f1}, wherein R_{f1} is a C₁-C₆ perfluoroalkyl group, such as CF₃ (PMVE), C₂F₅ or C₃F₇;
(e) perfluorooxyalkylvinylethers of formula CF₂═CFOX₀, wherein X₀ is a C₁-C₁₂ perfluorooxyalkyl group comprising one or more than one ethereal oxygen atom, including notably perfluoromethoxyalkylvinylethers of formula CF₂═CFOCF₂OR_{f2}, with R_{f2} being a C₁-C₃ perfluoro(oxy)alkyl group, such as —CF₂CF₃, —CF₂CF₂—O—CF₃ and —CF₃; and
(f) functional perfluoro(oxy)alkylvinylethers of formula CF₂═CFOY₀, wherein Y₀ is a C₁-C₁₂ perfluoro(oxy)alkylene group, optionally comprising one or more than one ethereal oxygen atom, which comprises at least one functional group selected from the group consisting of —SO₂X, —COX, —PO₂X, with X being a halogen or a —OXₐ group, with Xₐ being H, an ammonium group or a metal cation.

Fluoromonomer B is preferably a perfluoromonomer, and is more preferably selected from the group consisting of C₂-C₈ perfluoroolefins, and most preferably fluoromonomer B is tetrafluoroethylene (TFE).

Polymer (F) may comprise repeating units derived from monomers different from fluoromonomer A and fluoromonomer B; notably, polymer (F) may comprise recurring units derived from fluorine-free monomers, such as alpha-olefins (e.g. ethylene, propylene, butenes, hexenes), vinyl monomers (e.g. optionally substituted styrene-type monomers; (meth)acrylic monomers). Nevertheless, it is generally preferred for polymer (F) to consist essentially of monomers which are perfluorinated, that is to say which do not comprise any C-H moiety. Minor amounts (e.g. less than 1% moles, preferably less than 0.1% moles, with respect to overall moles of repeating units) of repeating units derived from hydrogen-containing monomers may be tolerated, without this significantly affecting performances of polymer (F). According to these embodiments, polymer (F) preferably essentially consists of:
repeating units having an alicyclic structure in main chain of said fluoropolymer and derived from at least one fluoromonomer A which is perfluorinated; and, optionally,
repeating unit derived from at least one fluoromonomer B different from fluoromonomer A, which is perfluorinated.

Polymer (F) is advantageously an amorphous polymer. The expression “amorphous” is hereby used in connection with polymer (F) for designating polymers which possess a heat of fusion of less than 5 J/g, preferably less than 3 J/g, more preferably less than 2 J/g, when determined according to ASTM D3418.

As said, according to a first variant of the present invention, polymer (F) may be a homopolymer essentially consisting of repeating units having an alicyclic structure in main chain of said fluoropolymer and derived from a fluoromonomer A which is perfluorinated. Homopolymers consisting of repeating units derived from a fluoromonomer A selected from the group consisting of perfluoro(2-methylene-4-methyl-1,3-dioxolane), perfluoro(2,2-dimethyl-1,3-dioxole), perfluoro(1,3-dioxole), 2,2,4-trifluoro-5-trifluoromethoxy-1,3-dioxole and perfluoro(3-butenyl vinyl ether) are exemplary preferred embodiments of polymer (F) according to this variant of the invention.

It is understood that because of their structure, repeating units having an alicyclic structure in main chain of said fluoropolymer and derived from a fluoromonomer A will generally lead to a homopolymer which is substantially amorphous, as above detailed.

According to other variants of the present invention, polymer (F) may comprise repeating units derived from at least one fluoromonomer B; these repeating units may or may not contribute to form crystalline domains in polymer (F).

Nevertheless, in general, when polymer (F) comprises repeating units derived from at least one fluoromonomer B, as detailed above, the respective amount of repeating units derived respectively from fluoromonomer A and fluoromonomer B are adjusted so that polymer (F) is substantially amorphous. According to these embodiments, polymer (F) comprises (and preferably consists essentially of):
from 20 to 95% moles, preferably from 30 to 80% moles, more preferably from 35 to 50% moles, with respect to the total moles of repeating units of polymer (F), of repeating units having an alicyclic structure in main chain of said fluoropolymer and derived from at least one fluoromonomer A, as above detailed; and
from 5 to 80% moles, preferably from 20 to 70% moles, more preferably from 50 to 65% moles, with respect to the total moles of repeating units of polymer (F), of repeating units derived from at least one fluoromonomer B different from fluoromonomer A, as above detailed.

The expression “consisting essentially of” when used in connection with polymer (F) and its constituting repeating units is to be understood to mean that defects, end chains, impurities, chains inversions or branchings and the like may be additionally present in the polymer (F) in addition to the recited repeating units, without these components substantially modifying the behaviour and properties of the polymer (F).

According to certain preferred embodiments of this variant, polymer (F) is a copolymer comprising:
repeating units having an alicyclic structure in main chain of said fluoropolymer and derived from at least one fluoromonomer A which is perfluorinated, as above detailed, and
repeating unit derived from at least one fluoromonomer B different from fluoromonomer A, which is perfluorinated, as above detailed.

More preferably, polymer (F) is a copolymer comprising:
repeating units derived from at least one fluoromonomer A selected from the group consisting of perfluoro(2-methylene-4-methyl-1,3-dioxolane), perfluoro(2,2-dimethyl-1,3-dioxole), perfluoro(1,3-dioxole), 2,2,4-trifluoro-5-trifluoromethoxy-1,3-dioxole and perfluoro(3-butenyl vinyl ether); and
repeating unit derived from tetrafluoroethylene (TFE).

Most preferably, polymer (F) is a copolymer comprising, preferably consisting essentially of:
repeating units derived from 2,2,4-trifluoro-5-trifluoromethoxy-1,3-dioxole; and
repeating unit derived from tetrafluoroethylene (TFE).

The intrinsic viscosity of polymer (F) can be determined using the Solomon-Ciuta equation on the basis of dropping time, at 30° C., of a solution obtained by dissolving the polymer (F) in Fluorinert® FC72 (known for being perfluorohexane) at a concentration of 1 g/dl using a Ubbelhode viscosimeter.

As said, polymer (F) possesses an intrinsic viscosity of less than 30 cc/g, preferably less than 25 cc/g, more preferably less than 20 cc/g, when determined in Fluorinert® FC72 (known for being perfluorohexane) as solvent at a temperature of 30° C.

While lower boundary for intrinsic viscosity is not particularly limited, it would be preferred for polymer (F) to possess an intrinsic viscosity of at least 5, preferably at least 7, more preferably at least 10 cc/g, when determined in Fluorinert® FC72 (known for being perfluorohexane) as solvent at a temperature of 30° C.

The expression “amount of carboxylic end groups” is hereby used to encompass the overall amount of carboxylic chain end in polymer (F) which may be present under their acidic form (—COOH), their acyl halide form (—COXₓ, with Xₓ being F, Cl or Br, generally Xₓ being F) and their carboxylate form (—COOX_{b}, with X_{b} being a (alkyl)ammonium, or a metal cation). Methods for determining amounts of carboxylic end groups in polymer (F) are known; said amount can be determined pursuant to the methodology described in PIANCA, M., et al. End groups in fluoropolymers. Journal of Fluorine Chemistry. 1999, vol.95, p.71-84.

As said, polymer (F) comprises an amount of carboxylic end groups of at most 8.0 mmol/kg, preferably at most 7.5 mmol/kg, more preferably at most 7.0 mml/kg, even more preferably at most 6.5 mmol/kg, still more preferably of at most 6.0 mmol/kg.

Lower amount of carboxylic end groups is not particularly critical; for instance, polymers (F) whereas carboxylic end groups are substantially absent, that it to say that their amount is below the detection limit of the method described above, may be used. According to other embodiments, polymers (F) whereas a minimum amount of carboxylic end groups is present may be used, and may be found advantageous, to the sake of delivering a certain advantageous adhesion to the underlying support layer. According to these embodiments, polymer (F) may possess an amount of carboxylic end groups which is at least detectable, or even of at least 0.5 or even at least 1.0 mmol/kg.

Tuning of viscosity, and of molecular weight and carboxylic end groups concentration may be achieved either during polymerization for manufacturing polymer (F), by acting on relative concentrations of inorganic peroxide initiators leading to the said polar end groups and acting on concentration of growing chains (so further impacting viscosity), chain transfer agents controlling viscosity but also introducing alternative chain terminations, and other polymerization parameters including monomers' concentration, pressure, temperature, etc [symbol] Further, post-treatment methods, such as fluorination, depolymerisation, irradiation, and the like, may be used for further increasing or decreasing viscosity and/or modify the nature of end groups.

For the purposes of the present invention, solvent (F) and solvent (P) have been characterized by means of their Hansen total solubility parameter δ_{T}; according to Hansen's approach, parameter δ_{T} is split into three components: polar, dispersion, and hydrogen bonding, wherein the equation 1, here below describes the relationship of the various components to the total solubility parameter δ_{T}:

δ_{T}²=δ_{D}²+δ_{P}²+δ_{H}² (eq. 1)

Solvents (F) which have been found particularly useful in the practice of the method of the present invention are those which have the following components:

| | |
|---|---|
| dispersion component, δ_{D} | from 11.0 to 14.50 |
| polar component, δ_{P} | from 0.1 to 5.0 |
| hydrogen bonding component, δ_{H} | from 0.0 to 2.0. |

From structural perspective, preferred solvents (F) are hydrofluoroethers (HFEs), i.e. ethers comprising partially fluorinated hydrocarbon structure, comprising both hydrogen and fluorine atoms bound to sp³-hybridized carbons.

Examples of readily available HFEs and isomeric mixtures of HFEs include, but are not limited to, an isomeric mixture of methyl nonafluorobutyl ether and methyl nonafluoroisobutyl ether (notably commercially available as NOVEC® HFE-7100), an isomeric mixture of ethyl nonafluorobutyl ether and ethyl nonafluoroisobutyl ether (notably commercially available as NOVEC® HFE-7200), 3-ethoxy-1,1,1,2,3,4,4,5,5,6,6,6-dodecafluoro-2-trifluoromethyl-hexane (notably commercially available as NOVEC® HFE-7500), 1-methoxyheptafluoropropane (notably commercially available as NOVEC® HFE-7000), 1,1,1,2,2,3,4,5,5,5-decafluoro-3-methoxy-4-trifluoromethylpentane (notably commercially available as NOVEC® HFE-7300).

Preferred solvents (F) are those possessing a normal boiling point of exceeding 60° C. and of at most 130° C.; more preferably, normal boiling point of solvent (F) is comprised between 60 and 110° C.

A solvent (F) which has been found particularly effective is 1,1,1,2,2,3,4,5,5,5-decafluoro-3-methoxy-4-trifluoromethylpentane (notably commercially available as NOVEC® HFE-7300).

As per solvents (P), it is preferred for solvent (P) to possess a solubility parameter of at most 25.5 MPa^{1/2}. Among solvents (P) whose solubility parameter δ_{T} is of at least 20.0 MPa^{1/2} and of at most 25.5 MPa^{1/2} mention may be notably made of cyclopentanol (δ_{T}=25.1 MPa^{1/2}), PGME (δ_{T}=21.9 MPa^{1/2}), cyclohexanol (δ_{T}=22.4 MPa^{1/2}). Cyclopentanol is particularly preferred.

The amount of solvent (P) is as said of 10 to 10000 ppm, preferably of 100 to 1500 ppm, based on weight of solvent (F).

Composition (C_{LO}) comprises at least one polymer (F), that is to say that it may comprise one or more than one polymer (F). Generally, composition (C_{LO}) comprises no other polymer component beyond polymer(s) (F) and may comprise certain amounts of additives, such as viscosity modifiers, stabilizers, anti-oxidants, UV-stabilizers, and the like. It is nevertheless generally understood that the stability of polymer (F) is generally such that use of additives may be avoided. According to preferred embodiments, hence, composition (C_{LO}) consists essentially of polymer (F), that is to say that minor amounts (e.g. of less than 1.0% wt, preferably less than 0.5% wt, more preferably less than 0.1% wt, with respect to overall weight of composition (C_{LO})) of impurities, additives or other ingredients may be tolerated, provided that their presence does not substantially affect the prominent features of layer (LO) of polymer (F).

According to certain embodiments, the method of the present invention is used in a process for producing a patterned structure on a substrate, which is another object of the present invention.

The process of producing a patterned structure on a substrate comprises the steps of:
(1) applying a composition (C_{LO}), comprising at least one polymer (F) on at least a portion of the substrate, so as to obtain a layer (LO) composition (C_{LO}) comprising polymer (F) onto said substrate;
(2) patterning the said layer (LO) so as to obtain a patterned layer (LO) comprising a pattern of covered and uncovered regions;
(3) at least partially removing uncovered regions of said patterned layer (LO), by contacting with a stripping solvent mixture according to the method of the invention, so as to obtain a patterned structure comprising a pattern of a layer (LO) on said substrate.

The step (1) of applying the composition (C_{LO}) may be effected by spreading said composition (C_{LO}) onto said substrate according to known coating techniques, including notably as doctor-blade coating, metering rod (or Meyer rod) coating, slot die coating, knife over roll coating, gap coating, spin coating and the like, so as to obtain a wet layer; subsequent at least partial removal of the liquid medium, as above detailed, would advantageously lead to the said lift-off layer onto said substrate. According to these embodiments, polymer (F) may be solubilized or dispersed in a liquid medium prior to step (1), and step (1) may hence comprise a step of removing said liquid medium. According to these embodiments, the liquid medium generally comprises at least one organic solvent. The said organic solvent may be selected from the group consisting of organic solvents containing at least one fluorine atoms, including notably perfluoroalkanes, perfluoroethers, hydrofluoroethers, fluoro-amines, perfluoro-amines, fluoro-cyclic organic compounds or mixtures thereof. HFE, as described above in connection with solvent (F) may be used. To the sake of minimizing the number of different liquid media used in the method, liquid medium may be the same as the stripping solvent mixture. Liquid medium is generally removed and recovered by evaporation; in case liquid medium is the same as the same as the stripping solvent mixture.

Step (2) comprises patterning the said layer (LO) so as to obtain a patterned layer (LO) comprising a pattern of covered and uncovered regions. Methods of achieving said patterning are not particularly limited. According to preferred embodiments, step (2) comprises:
a sub-step (2A) of forming a layer of a photoresist on said layer (LO), so as to obtain a photoresist layer;
a sub-step (2B) of exposing said photoresist layer to patterned radiation, so as to obtain a patterned photoresist layer comprising radiation-modified and non-radiation modified regions; and
a sub-step (2C) of substantially removing either of the said radiation-modified and non-radiation modified regions, so as to obtain a patterned layer (LO) comprising a pattern of photoresist-covered and photoresist-uncovered regions.

The choice of photoresist is not particularly limited. Photoresists well known in the art can be used, including positive and negative photoresists, that is to say photoresists whereas exposure to radiation makes the same more easily removable, e.g. more soluble (so-called “positive” photoresists) and photoresists whereas exposure to radiation makes the same less removable, e.g. less soluble, for instance via crosslinking/polymerisation (so-called “negative” photoresists).

The step (2B) of exposing the photoresist to patterned radiation may be obtained by irradiating the photoresist layer obtained from step (2A) interposing a mask opaque to radiation and possessing a patterned structure between the radiation source and the said photoresist layer.

When a positive photoresist is used, step (2B) may provide for radiation-modified region of the photoresist layer which are chemically modified, e.g. to effect de-polymerization/degradation and hence have advantageously acquired significant solvent-solubility and non-radiation modified regions of the said photoresist layer which have not been affected, and which hence advantageously maintain appreciable solvent-resistance.

When a negative photoresist is used, step (2B) may provide for radiation-modified region of the photoresist layer which are cured and hence have advantageously acquired significant solvent-resistance and non-radiation modified regions of the said photoresist layer which are not cured, and which hence advantageously maintain appreciable solvent solubility.

In sub-step (2C), generally either of said radiation modified regions or said non-radiation modified regions of the photoresist layer are advantageously removed. Removal of said regions may be achieved by standard means; it is nonetheless understood that treatment with an organic solvent will be among preferred means for the removal of either of said radiation modified regions or said non-radiation modified regions. The organic solvent used in this sub-step (2C) will be selected by one of ordinary skills in the art depending on the nature of the photoresist, among those which preferably are not able to attack neither the underlying layer (LO).

Result of sub-step (2C) is hence a patterned layer (LO) comprising a pattern of photoresist-covered and photoresist-uncovered regions, whereas advantageously the photoresist-covered regions are regions of layer (LO) covered by regions of the photoresist layer which have not been removed in sub-step (2C).

In step (3), uncovered regions of said patterned layer (LO) of polymer (F) are at least partially removed, so as to obtain a patterned structure comprising a pattern of layer (LO) on said substrate, according to the method of the present invention.

The process for producing a patterned structure on a substrate of the present invention may comprise additional steps, wherein the patterned structure obtained in Step (3) is used as an intermediate structure for deposing and/or patterning and/or removing additional layers.

Notably, the said process may comprise a step (4) of applying an additional coating layer of a material (M) on the patterned structure comprising a pattern of a layer (LO) on said substrate, so as to obtain a patterned structure comprising a pattern of the layer (LO) coated with material (M); and may comprise an additional subsequent step (5) of removing the said pattern of the layer (LO) coated with material (M) so as to obtain a patterned structure comprising corresponding negative pattern of layer of material (M).

Material (M) may be an organic semiconductor material, an organometallic material, a biological material, a metallic material and the like.

Similarly, the choice of the substrate is not particularly limited, and will depend upon the intended use of the patterned structure. For instance, substrate made of polyimides (PI), polyethyleneterephthalate (PET), polyethylene naphthalate (PEN), polyetherimide (PEI), polyamideimide (PAI), glass, silicon, silicon oxide, transparent mixed oxides such as indium tin oxides (ITO), indium zinc oxide, aluminium-doped zinc oxide (AZO), indium-doped cadmium oxide; aluminium, gallium or indium-doped zinc oxide (AZO, GZA or IZO), formulations containing carbon nanotubes, graphene, silver nanoparticles; inherently conductive polymers such as polyanilines, PEDOT:PSS.

Substrates are generally flattened in shape, and may have the form of sheets or films, including flexible films. Substrates may comprise electrodes or other types of electrical connections, including notably metallic electrodes of Cu, Al, Mo, Ag, Mg or alloys combining more than one of said metallic elements.

Should the disclosure of any of the patents, patent applications, and publications that are incorporated herein by reference conflict with the present description to the extent that it might render a term unclear, the present description shall take precedence.

The present invention will be now described in more detail with reference to the following examples, whose purpose is merely illustrative and not limitative of the scope of the invention.

### EXAMPLES

### Raw materials

As fluoropolymers, use has been made of several different amorphous perfluorocopolymers consisting essentially of repeating units derived from 2,2,4-trifluoro-5-trifluoromethoxy-1,3-dioxole; and repeating unit derived from tetrafluoroethylene (TFE); more particularly
(FC-1): Fluoropolymer (FC-1) is an amorphous perfluoropolymer possessing an intrinsic viscosity of 38 cc/g and a concentration of carboxylic end groups of 9 mmol/kg;
(FC-2): Fluoropolymer (FC-2) is an amorphous perfluoropolymer possessing an intrinsic viscosity of 14 cc/g and a concentration of carboxylic end groups of 20 mmol/kg;
(FC-3): Fluoropolymer (FC-3) is an amorphous perfluoropolymer possessing an intrinsic viscosity of 33 cc/g and a concentration of carboxylic end groups of below detection limit of used technique;
(F-1): Fluoropolymer (F-1) is an amorphous perfluoropolymer possessing an intrinsic viscosity of 12 cc/g and a concentration of carboxylic end groups of below detection limit of used technique. (FC-1), (FC-2) and (FC-3) have been used in comparative examples, while (F-1) is the polymer (F) employed in the inventive examples.

### Determination of Intrinsic Viscosity of Polymer (F)

Intrinsic viscosity (η) [dl/g] was determined using the Solomon-Ciuta equation (reproduced below), measuring dropping time, at 30° C., of a solution obtained by dissolving the polymer (F) in FLUORINERT® FC72 (perfluorohexane) at a concentration of 1 g/dl using a Ubbelhode viscosimeter:

$$[ η ] = \frac{{[ 2 ( {η}_{s p} - ln ( {η}_{r} ) ) ]}^{1 / 2}}{c} ( Solomon ‐ Ciuta equation )$$

where c is polymer concentration [g/dl], ηᵣ is the relative viscosity, i.e. the ratio between the dropping time of sample solution and the dropping time of solvent, ηₛₚ is the specific viscosity, i.e. ηᵣ-1.

### Determination of Carboxylic End Groups of Polymer (F)

Amount of carboxylic end groups were determined according to the method described in PIANCA, M., et al. End groups in fluoropolymers. Journal of Fluorine Chemistry. 1999, vol.95, p.71-84. Concentration of relevant chain ends are expressed as mmoles of groups per kg of polymer (F) and encompasses carboxylic end groups in their acidic form (—COOH), acyl halide form (—COF) and salified form (—COOX_{b}, with X_{b} being (alkyl)amonium or metal cation). Detection limit of the determination of carboxylic end groups is 0.1 mmol/Kg.

### Determination of the Thickness of Layers on the Substrate

The thickness of layers deposed onto a substrate was determined by using a Filmetrics F50 Automated Film Thickness Mapping. The complex refractive index values of polymer (F) used for calculating the thickness from the reflectance spectra were n_{489 nm}=1.331; k_{489 nm}=0 n_{589 nm}=1.329; k_{589 nm}=0; n_{656 nm}=1.328; k_{656 nm}=0.

### Preparation of Stripper Solvent Mixture [Stripper (SM-1), Herein After]

10g of Cyclopentanol (purchased from Sigma-Alrich) was added with 1990 g of NOVEC® 7300 (purchased from 3M) in a 2 L plastic bottle. The plastic bottle was shaken during 1 hour, so obtaining a blend of cyclopentanol and NOVEC® 7300 with a cyclopentanol concentration of 0.5 wt. %.

### Embodiments 1 to 3

A layer of 20 nm of LG201 material (purchased from LG chemical, acting as ETL{electron transfer layer}) was deposited on 1 inch wafer by using thermal evaporating method (LESKER Co.,LTD., KJLL Spectros Deposition system.)

On the so prepared ETL-comprising wafer substrate, a solution of polymer was coated by spin coating method in the conditions below detailed: Spin coater: SUSS Mircrotec Delta6RC, at 1600 rpm, for 50 s.

The coated ETL-containing wafer substrate was baked on a hotplate at 100° C. for 10 min, so as to form a lift-off layer of polymer (F-1) or of comparative polymers (FC-1) to (FC-3), having a thickness of about 1 μm. Lift-off layer was removed by using stripper solvent mixtures as detailed in the examples below, by dipping into a bath of stripping medium, followed by drying.

### Determination of F-residues on LG201(ETL) Layer after Stripping of Lift-off Layer

TOF-SIMs analysis, using TOFSIMS 5 apparatus from ionTOF company was used to determine F-residues, in the following conditions: 60 Kev, current: 0.38 pA, Area 500×500 μm². The intensity of the peaks detected at m/z=19 (F-ions); m/z=31 (CF-ions) and m/z=38 (F₂-ions) has been normalized to the intensity of the same peaks detected from the LG201 neat surface.

Results are summarized in the table below, whereas:
Ex. 1C (of comparison) provides for measurements of F-residues after a) formation of a layer (OL) of polymer (FC-1) and b) removal of the same by dipping in neat Novec® 7300;
Ex. 2C (of comparison) provides for measurements of F-residues after a) formation of a layer (OL) of polymer (FC-1) and b) removal of the same using stripper (SM-1);
Ex. 3C: (of comparison) provides for measurements of F-residues after a) formation of a layer (OL) of polymer (FC-2) and b) removal of the same using neat NOVEC® 7300;
Ex. 4C (of comparison): provides for measurements of F-residues after a) formation of a layer (OL) of polymer (FC-2) and b) removal of the same using stripper (SM-1);
Ex. 5 (according to the invention): provides for measurements of F-residues after a) formation of a layer (OL) of polymer (F) and b) removal of the same using stripper (SM-1);
Ex. 6C (of comparison): provides for measurements of F-residues after a) formation of a layer (OL) of polymer (FC-3) and b) removal of the same using stripper (SM-1).

TABLE 1

| | Peak area | | |
|---|---|---|---|
| | F⁻ | CF⁻ | F₂⁻ |
| Ref. (LG201 layer) | 1 | 1 | 1 |
| Ex. 1C | 345.75 | 333.43 | 2982.92 |
| Ex. 2C | 179.97 | 149.75 | 685.14 |
| Ex. 3C | 339.28 | 313.84 | 2601.51 |
| Ex. 4C | 112.53 | 86.4 | 131.2 |
| Ex. 5 | 2.18 | 1.81 | 1.89 |
| Ex. 6C | 18.87 | 15.11 | 20.26 |

Table above clearly demonstrate that best performance in terms of effective removal of layer (OF) is obtained when combining the choice of the polymer (F) with the stripper solvent mixture, according to the method of the present invention.

### Manufacture and Performance of OLED Devices

OLED device having the structure described above were manufactured:
ITO
substrate/HATCN(5 nm)/HT011(50 nm)/HATCN(5 nm)/HT211(140 nm)/NS60:H111:GD270(40 nm)[43.5:43.5:13]/LG201(30 nm)→layer (LO)→removal with stripper/Liq(1 nm)/Al(100 nm).

The following raw materials were used:
HIL layer. HATCN(1,4,5,8,9,11-Hexaazatriphenylenehexacarbonitrile), HT011 (N4,N4′Di(naphthalen-1-yl)-N4,N4′-diphenylbiphenyl-4,4′-diamine)
HTL layer. HT211(N-[1,1′-Diphenyl]-4-yl-9,9-dimethyl-N-[4-(9-phenyl-9H-carbazol-3-yl)phenyl]-9H-fluoren-2-amine)
EML layer. NS60 (Trade name from Nippon Steel Chemical Co., Ltd.), H111(4-[3-(2-triphenylenyl)phenyl]-Dibenzothiophene), GD270 (Trade name from P&H Tech.)
ETL layer. LG201 (Trade name from LG Chemical Co., Ltd.)
EIL layer. Liq(8-Quinolinolato lithium) Cathode electrode: Al (Kojundo co., Ltd. from Japan.)

The devices were prepared according to the below detailed procedure:
1^{st} deposition (HIL˜ETL)
   1) ITO substrate was cleaned with ultra-sonic process using de-ionized water for 10 min and then isopropanol for 10 min.
   2) Surface of the ITO substrate was treated with oxygen plasma (Condition: (120 W, Ar 4 L/min, O₂ 12 mL/min, Levi system co., LTD from Korea)
   3) The plasma-treated ITO substrate was introduced into a vacuum chamber for OLED material deposition.
   4) OLED material was deposited on the substrate under high vacuum (less than 10⁻⁷ torr vacuum condition).
I. Forming layer (LO) on ETL
   1) The ITO substrate having ETL layer was recovered from the vacuum chamber and moved into a glove box where the ITO substrate was packed to prevent exposure to air.
   2) Polymer (F-1) and/or (FC-1) to (FC-3) were coated on surface of ETL at fixed spin coating condition. (Spin coater: SUSS Mircrotec Delta6RC, at 1600 rpm, 50 s.)
   3) The sample substrate was dried on hotplate at 100° C. for 10 min.
II. Stripping layer (LO)
   1) The sample substrate was dipped in a stripper bath during 10 minutes for removal of layer (LO) from surface of ETL.
   2) The sample substrate was dried on hot plate at 100° for 10 min.
III. 2^{nd} deposition (EIL˜Al)
   1) The sample substrate was packed to prevent exposure to air and taken out from the glove box.
   2) The sample substrate was introduced into vacuum chamber.
   3) OLED material was deposited on the sample substrate under high vacuum (less than 10-7 torr vacuum condition).
   4) The sample substrate was encapsulated in glove box after Al deposition, so as to obtain a device.
IV. Evaluation of device performances
   1) IVL device characteristics was measured with radio spectrometer. EQE (in %) and voltage (V) @ 10 mA/cm² was determined (CS2000 Konica-Minolta from Japan).
   2) Lifetime of device was measured with OLED lifetime system under constant current density (BO TEST Co.LTD—Poland).

Results are summarized in Table 2 below:

TABLE 2

| | | Ref. | Device 1 | Device 2C | Device 3C | Device 4C |
|---|---|---|---|---|---|---|
| Lift off layer | | — | Polymer | Polymer | Polymer | Polymer |
| | | | (F-1) | (FC-1) | (FC-1) | (FC-2) |
| Stripper | stripper (SM-1) | n.a. | yes | no | yes | yes |
| | Novec ® 7300 | n.a. | no | yes | no | no |
| Device | Operating | 10.50 | 10.61 | 2.31 | 9.41 | 9.50 |
| performances | voltage (V) | | | | | |
| | EQE | 4.38 | 4.34 | 6.88 | 4.91 | 4.89 |

Data above summarized well demonstrate that performances of device (1) are substantially identical to those observed with reference OLED device of same constituting structure, but where no lift-off layer was formed and subsequently removed.

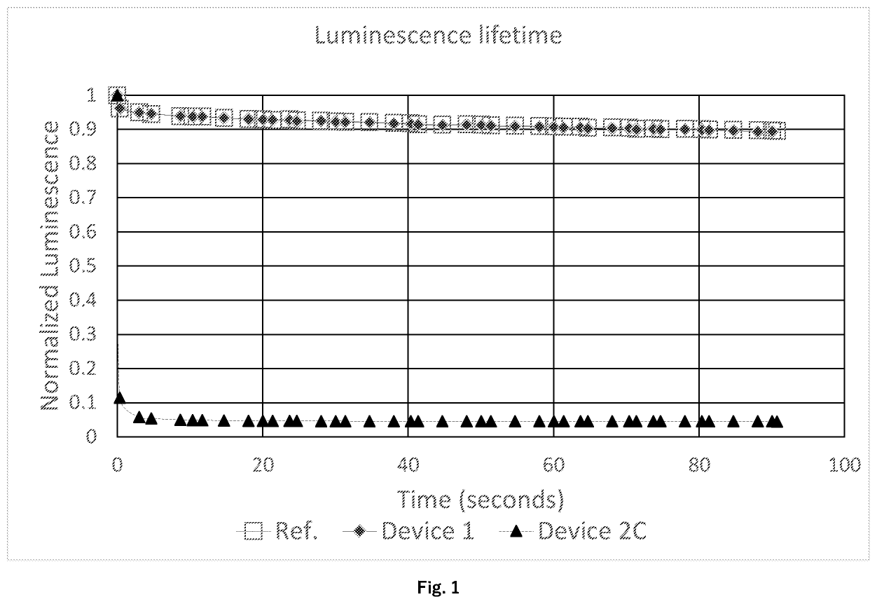

Luminesce life-time of reference OLED device, device (1) and device (2C) of comparison is sketched in FIG. 1; device (1), which has been manufactured using notably the method of the present invention, possesses luminescence time-profile substantially undistinguishable from luminescence time-profile of reference OLED device, while comparative device (2C) displays a significant decay in luminescence.

1. A method of at least partially removing a lift-off layer (layer (LO)) made of a composition (Cu_{LO}) comprising at least one fluoropolymer comprising:
repeating units having an alicyclic structure in main chain of said fluoropolymer and derived from at least one fluoromonomer A, and, optionally,
repeating units derived from at least one fluoromonomer B different from fluoromonomer A,
said fluoropolymer:
possessing an intrinsic viscosity of less than 30 cc/g, when measured at 30° C. in perfluorohexane as solvent; and
comprising an amount of carboxylic end groups of less than 8 mmol/kg (polymer (F));
said method comprising:
providing an assembly comprising a support material having regions covered by a layer (LO);
contacting said assembly with a stripping solvent mixture comprising:
a) at least one fluorinated solvent (solvent (F)) having a Hansen solubility parameter δ_{T} of less than 15.0 MPa^{1/2};
b) from 10 to 10000 ppm, based on weight of solvent (F), of at least one polar organic solvent different from solvent (F) (solvent (P)), said solvent (P) possessing a Hansen solubility parameter δ_{T} of at least 20.0 MPa^{1/2} and of at most 26.0 MPa^{1/2},
so as to obtain at least partial removal of said layer (LO).

2. The method of claim 1, wherein fluoromonomer A is selected from the group consisting of fluoromonomers having an alicyclic structure in their monomeric form and fluoromonomers which do not have an alicylic structure in their monomeric form, but which upon cyclopolymerization provide for an alicyclic structure in the resulting repeating unit of polymer (F), and wherein fluoromonomer A is a perfluoromonomer.

3. The method of claim 2, wherein the repeating unit derived from said fluoromonomer A is represented by any one of the following formulae (1) to (3): 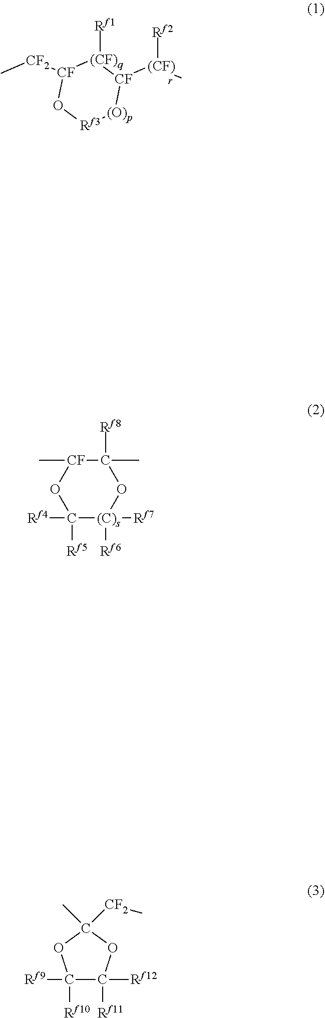
wherein:
in the formula (1) each of p, q and r which are independent of each other, is 0 or 1, each of R^{f1} and R^{f2} which may be the same or different, is a fluorine atom, a C₁-C₅ perfluoroalkyl group or a C₁-C₅ perfluoroalkoxy group, and R^{f3} is a C₁-C₃ perfluoroalkylene group, which optionally has a C₁-C₅ perfluoroalkyl group or a C₁-C₅ perfluoroalkoxy group, as a substituent;
in the formula (2), s is 0 or 1, each of R^{f4}, R^{f5}, R^{f6} and R^{f7} which may be the same or different, is a fluorine atom or a C₁-C₅ perfluoroalkyl group, and R^{f8} is a fluorine atom, a C₁-C₅ perfluoroalkyl group or a C₁-C₅ perfluoroalkoxy group, provided that R^{f4} and R^{f5} may be connected to form a spiro ring when s=0; and
in the formula (3), each of R^{f9}, R^{f10}, R^{f11} and R^{f12} which may be the same or different, is a fluorine atom or a C₁-C₅ perfluoroalkyl group or a C₁-C₅ perfluoroalkoxy group.

4. The method of claim 3, wherein the repeating unit derived from said fluoromonomer A complies with formula (1), and is selected from the group consisting of those represented by the following formulae (4) to (19):

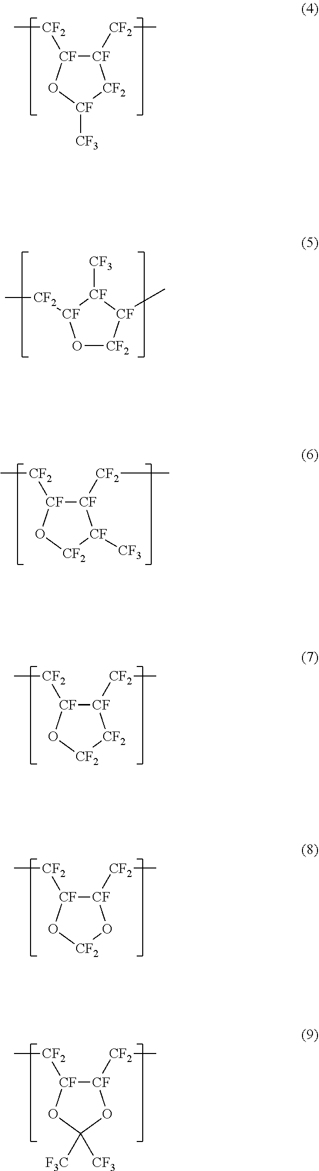

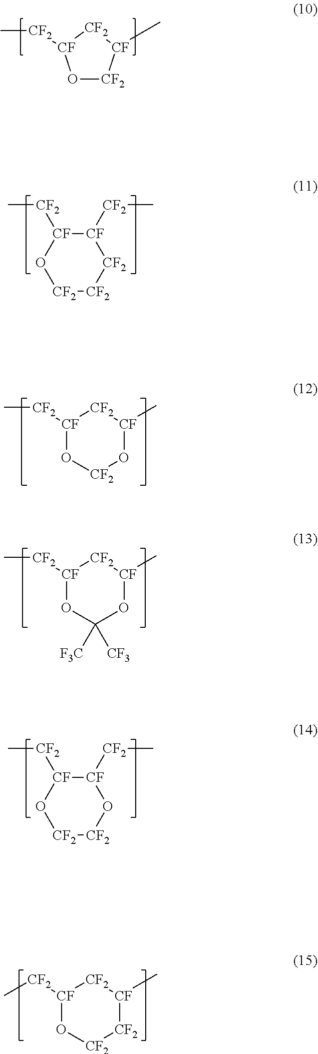

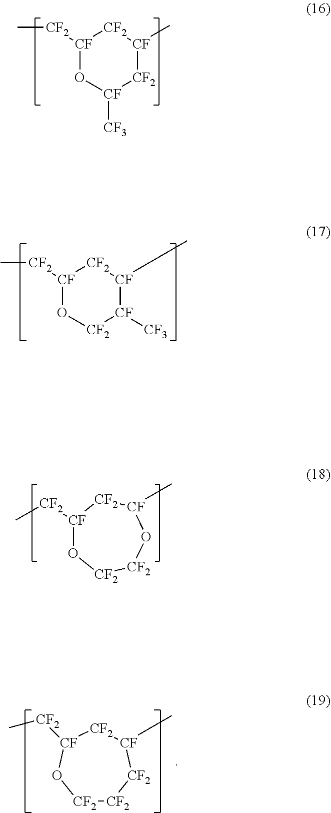

5. The method of claim 3, wherein the repeating unit derived from said fluoromonomer A complies with formula (2), and is selected from the group consisting of those represented by the following formulae (20) to (30):

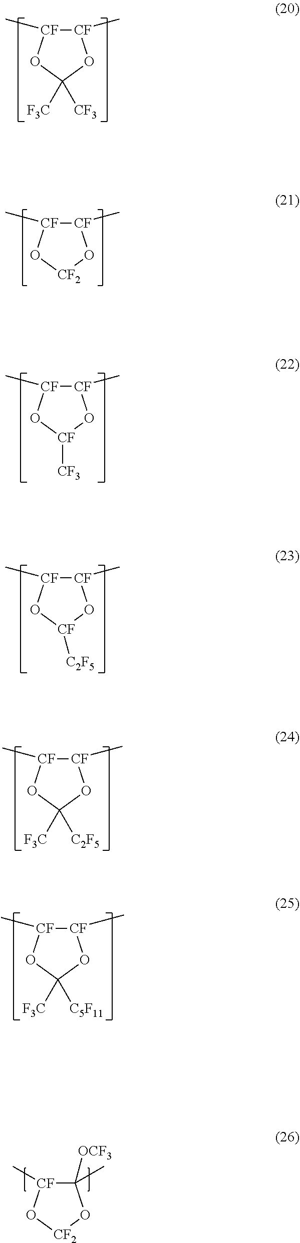

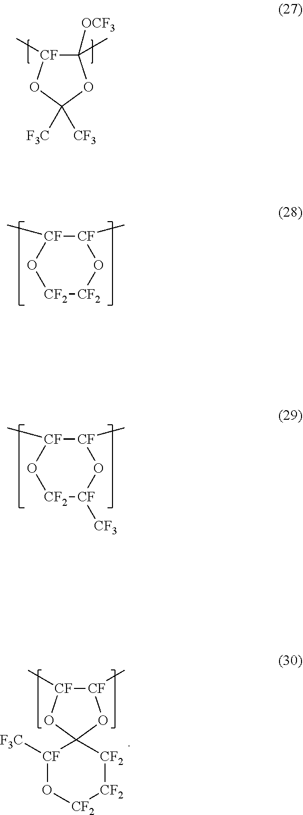

6. The method of claim 3, wherein the repeating unit derived from said fluoromonomer A complies with formula (2), and is selected from the group consisting of those represented by the following formulae (31) to (33):

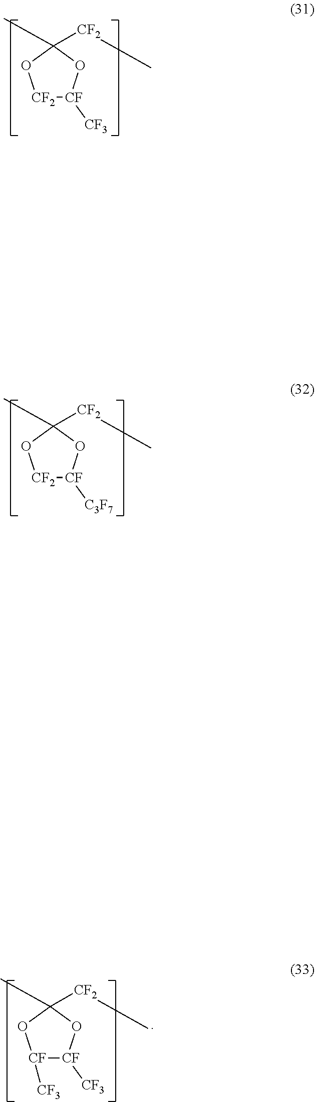

7. The method according to claim 1, wherein polymer (F) comprises repeating units derived from at least one fluoromonomer B different from fluoromonomer A, wherein fluoromonomer B is selected from the group consisting of:
(a) C₂-C₈ perfluoroolefins;
(b) hydrogen-containing C₂-C₈ fluoroolefins;
(c) C₂-C₈ chloro- and/or bromo-containing fluoroolefins;
(d) perfluoroalkylvinylethers (PAVE) of formula CF₂═CFOR_{f1}, wherein R_{f1} is a C₁-C₆ perfluoroalkyl group;
(e) perfluorooxyalkylvinylethers of formula CF₂═CFOX₀, wherein X₀ is a C₁-C₁₂ perfluorooxyalkyl group comprising one or more than one ethereal oxygen atom; and
(f) functional perfluoro(oxy)alkylvinylethers of formula CF₂═CFOY₀, wherein Y₀ is a C₁-C₁₂ perfluoro(oxy)alkylene group, optionally comprising one or more than one ethereal oxygen atom, which comprises at least one functional group selected from the group consisting of —SO₂X, —COX, —PO₂X, with X being a halogen or a —OXₐ group, with Xₐ being H, an ammonium group or a metal cation.

8. The method according to claim 7, wherein said polymer (F) comprises:
from 20 to 95% moles, with respect to the total moles of repeating units of polymer (F), of repeating units having an alicyclic structure in main chain of said fluoropolymer and derived from at least one fluoromonomer A; and
from 5 to 80% moles, with respect to the total moles of repeating units of polymer (F), of repeating units derived from at least one fluoromonomer B different from fluoromonomer.

9. The method according to claim 8, wherein polymer (F) is a copolymer comprising:
repeating units derived from at least one fluoromonomer A selected from the group consisting of perfluoro(2-methylene-4-methyl-1,3-dioxolane), perfluoro(2,2-dimethyl-1,3-dioxole), perfluoro(1,3-dioxole), 2,2,4-trifluoro-5-trifluoromethoxy-1,3-dioxole and perfluoro(3-butenyl vinyl ether); and
repeating units derived from tetrafluoroethylene (TFE).

10. The method according to claim 1, wherein said polymer (F):
comprises an amount of carboxylic end groups ranging from an amount which is not detectable to an amount of at most 7.5 mmol/kg; and/or
possesses an intrinsic viscosity of less than 25 cc/g and/or of at least 5 cc/g.

11. The method according to claim 1, wherein solvent (F) is selected from the group consisting of those possessing the following solubility parameter components:

| | |
|---|---|
| dispersion component, δ_{D} | from 11.0 to 14.50 |
| polar component, δ_{P} | from 0.1 to 5.0 |
| hydrogen bonding component, δ_{H} | from 0.0 to 2.0. |

12. The method according to claim 11, wherein solvent (F) is selected from the group consisting from hydrofluoroethers (HFEs) which are ethers comprising partially fluorinated hydrocarbon structure, comprising both hydrogen and fluorine atoms bound to sp³-hybridized carbons.

13. The method according to claim 1, wherein solvent (P) is selected from solvents whose solubility parameter δ_{T} is of at least 20.0 MPa^{1/2} and of at most 25.5 MPa^{1/2}; and/or wherein the amount of solvent (P) is of 100 to 1500 ppm, based on the weight of solvent (F).

14. A process for producing a patterned structure on a substrate, wherein the process comprises the steps of:
(1) applying a composition (C_{LO}) comprising at least one fluoropolymer comprising:
repeating units having an alicyclic structure in main chain of said fluoropolymer and derived from at least one fluoromonomer A, and, optionally,
repeating units derived from at least one fluoromonomer B different from fluoromonomer A,
said fluoropolymer:
possessing an intrinsic viscosity of less than 30 cc/g, when measured at 30° C. in perfluorohexane as solvent; and
comprising an amount of carboxylic end groups of less than 8 mmol/kg (polymer (F)) on at least a portion of the substrate, so as to obtain a layer (LO) composition (C_{LO}) comprising polymer (F) onto said substrate;
(2) patterning the said layer (LO) so as to obtain a patterned layer (LO) comprising a pattern of covered and uncovered regions;
(3) at least partially removing uncovered regions of said patterned layer (LO), by contacting with a stripping solvent mixture according to the method of claim 1, so as to obtain a patterned structure comprising a pattern of a layer (LO) on said substrate.

15. The process of claim 14, wherein:
Step (2) comprises:
a sub-step (2A) of forming a layer of a photoresist on said layer (LO), so as to obtain a photoresist layer;
a sub-step (2B) of exposing said photoresist layer to patterned radiation, so as to obtain a patterned photoresist layer comprising radiation-modified and non-radiation modified regions; and
a sub-step (2C) of substantially removing either of the said radiation-modified and non-radiation modified regions, so as to obtain a patterned layer (LO) comprising a pattern of photoresist-covered and photoresist-uncovered regions; and/or
the process comprises additional Step (4) of applying an additional coating layer of a material (M) on the patterned structure comprising a pattern of a layer (LO) on said substrate, so as to obtain a patterned structure comprising a pattern of the layer (LO) coated with material (M);
and may comprise an additional subsequent Step (5) of removing the said pattern of the layer (LO) coated with material (M) so as to obtain a patterned structure comprising corresponding negative pattern of layer of material (M), wherein material (M) may be an organic semiconductor material, an organimetallic material, a biological material, and a metallic material; and/or
wherein substrate may be made of polyimides (PI), polyethyleneterephthalate (PET), polyethylene naphthalate (PEN), polyetherimide (PEI), polyamideimide (PAI), glass, silicon, silicon oxide, transparent mixed oxides; aluminium, gallium or indium-doped zinc oxide (AZO, GZA or IZO), formulations containing carbon nanotubes, graphene, silver nanoparticles; inherently conductive polymers.

16. The method according to claim 7, wherein said polymer (F) consists essentially of:
from 20 to 95% moles, with respect to the total moles of repeating units of polymer (F), of repeating units having an alicyclic structure in main chain of said fluoropolymer and derived from at least one fluoromonomer A; and
from 5 to 80% moles, with respect to the total moles of repeating units of polymer (F), of repeating units derived from at least one fluoromonomer B different from fluoromonomer A.

17. The method according to claim 16, wherein fluoromonomer A and fluoromonomer B are perfluorinated.

18. The method according to claim 8, wherein polymer (F) is a copolymer consisting essentially of:
repeating units derived from at least one fluoromonomer A selected from the group consisting of perfluoro(2-methylene-4-methyl-1,3-dioxolane), perfluoro(2,2-dimethyl-1,3-dioxole), perfluoro(1,3-dioxole), 2,2,4-trifluoro-5-trifluoromethoxy-1,3-dioxole and perfluoro(3-butenyl vinyl ether); and
repeating units derived from tetrafluoroethylene (TFE).

19. The method according to claim 18, wherein polymer (F) is a copolymer consisting essentially of:
repeating units derived from 2,2,4-trifluoro-5-trifluoromethoxy-1,3-dioxole; and
repeating unit derived from tetrafluoroethylene (TFE).

20. The method according to claim 11, wherein solvent (F) is selected from the group consisting of:
an isomeric mixture of methyl nonafluorobutyl ether and methyl nonafluoroisobutyl ether;
an isomeric mixture of ethyl nonafluorobutyl ether and ethyl nonafluoroisobutyl ether;
3-ethoxy-1,1,1,2,3,4,4,5,5,6,6,6-dodecafluoro-2-trifluoromethyl-hexane;
1-methoxyheptafluoropropane; and
1,1,1,2,2,3,4,5,5,5-decafluoro-3-methoxy-4-trifluoromethylpentane.
